(19) United States
(12) Patent Application Publication
(10) Pub. No.: US 2023/0411312 A1
(43) Pub. Date: Dec. 21, 2023

(54) SEMICONDUCTOR CHIP AND SEMICONDUCTOR DEVICE

(71) Applicant: ROHM Co., LTD., Kyoto (JP)

(72) Inventor: Daisuke UCHIMOTO, Kyoto (JP)

(21) Appl. No.: 18/333,977

(22) Filed: Jun. 13, 2023

(30) Foreign Application Priority Data
Jun. 17, 2022 (JP) 2022-098202

(51) Int. Cl. H01L 23/62; H01L 23/00; H03K 17/082

(52) U.S. Cl. CPC H01L 23/62; H01L 24/48; H03K 17/0822; H01L 2224/48175; G05F 1/573

(57) ABSTRACT

Disclosed herein is a semiconductor chip including a power transistor, a plurality of pads, a plurality of wires arranged to establish continuity between each of the plurality of pads and a first end or a second end of the power transistor, a current detection circuit configured to detect, as a sense voltage, at least one of voltage drops caused in each of the plurality of wires according to a branch current flowing through the wire and a wire resistance component of the wire, and a logic configured to determine a condition of wire bonding of each of the plurality of pads according to a result of the detection by the current detection circuit.

### CROSS REFERENCE TO RELATED APPLICATIONS

This application claims priority benefit of Japanese Patent Application No. JP 2022-098202 filed in the Japan Patent Office on Jun. 17, 2022. Each of the above-referenced applications is hereby incorporated herein by reference in its entirety.

### BACKGROUND

The present disclosure relates to a semiconductor chip and a semiconductor device.

In many semiconductor devices that handle a large electric current, a plurality of wires are arranged in parallel to establish bonding between pads and an external electrode for branching of an electric current (see, for example, Japanese Patent Laid-open No. 2006-109665, Japanese Patent Laid-open No. 2008-236528, and Japanese Patent Laid-open No. 2004-080087).

### BRIEF DESCRIPTION OF THE DRAWINGS

FIG. 1 is a diagram illustrating a first comparative example of a semiconductor device;

FIG. 2 is a diagram illustrating a second comparative example of a semiconductor device;

FIG. 3 is a diagram illustrating a semiconductor device according to a first embodiment of the present disclosure;

FIG. 4 is a diagram illustrating a semiconductor device according to a second embodiment of the present disclosure;

FIG. 5 is a diagram illustrating a circuit layout (in which metal wires are not depicted) of the second embodiment; and

FIG. 6 is a diagram illustrating the circuit layout (in which the metal wires are depicted) of the second embodiment.

### DETAILED DESCRIPTION

### Semiconductor Device (First Comparative Example)

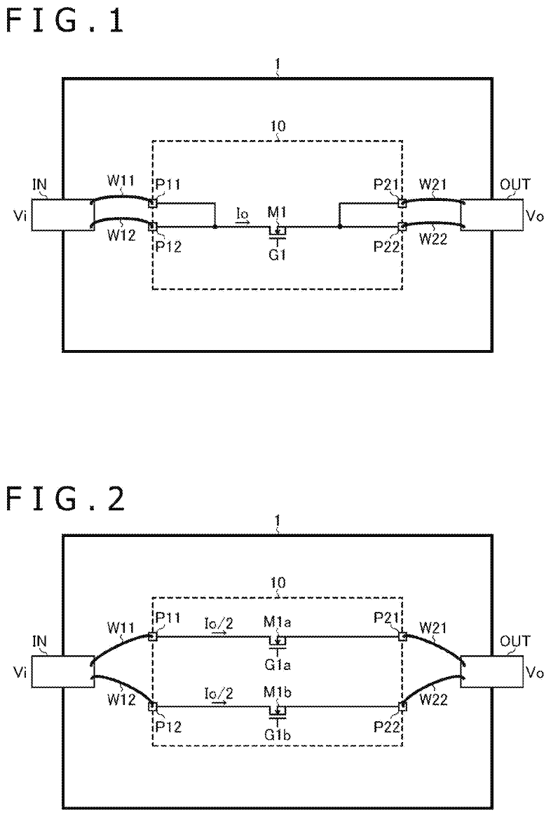

FIG. 1 is a diagram illustrating a first comparative example of a semiconductor device (which has a typical configuration to be compared with the configurations of a first embodiment and a second embodiment of the present disclosure, which will be described below). A semiconductor device 1 according to the present comparative example includes a semiconductor chip 10, an input electrode IN, an output electrode OUT, and wires W11, W12, W21, and W22 encapsulated in a package.

Various circuit elements (not illustrated) including a power transistor M1 (e.g., an N-channel type metal oxide semiconductor field effect transistor (NMOSFET)) are integrated in the semiconductor chip 10. In addition, the semiconductor chip 10 includes pads P11, P12, P21, and P22 to achieve electrical continuity with each of the input electrode IN and the output electrode OUT.

The power transistor M1 is connected between the pads P11 and P12 and the pads P21 and P22. In FIG. 1, a drain of the power transistor M1 is connected to each of the pads P11 and P12. A source of the power transistor M1 is connected to each of the pads P21 and P22. A gate of the power transistor M1 is connected to a terminal for applying a gate signal G1.

The on-resistance of the power transistor M1 varies according to the gate signal G1. In a case where the power transistor M1 is an NMOSFET, the on-resistance of the power transistor M1 decreases as the value of the gate signal G1 increases, and increases as the value of the gate signal G1 decreases. Accordingly, an output current Io that flows through the power transistor M1 increases as the value of the gate signal G1 increases, and decreases as the value of the gate signal G1 decreases.

The input electrode IN is an external electrode to which an input voltage Vi is applied. Note that one end of the input electrode IN is exposed from the package of the semiconductor device 1.

The output electrode OUT is an external electrode to which an output voltage Vo is applied. Note that one end of the output electrode OUT is exposed from the package of the semiconductor device 1.

The wires W11 and W12 are installed in such a manner as to establish bonding between another end of the input electrode IN and the pads P11 and P12, respectively, of the semiconductor chip 10.

The wires W21 and W22 are installed in such a manner as to establish bonding between another end of the output electrode OUT and the pads P21 and P22, respectively, of the semiconductor chip 10.

As described above, in the semiconductor device 1 according to the present comparative example, the input electrode IN and the semiconductor chip 10 are bonded to each other through the wires W11 and W12 in a parallel manner. This enables the output current Io flowing from the input electrode IN toward the power transistor M1 to flow partially through the wire W11 and partially through the wire W12. Similarly, in the semiconductor device 1 according to the present comparative example, the semiconductor chip 10 and the output electrode OUT are bonded to each other through the wires W21 and W22 in a parallel manner. This enables the output current Io flowing from the power transistor M1 toward the output electrode OUT to flow partially through the wire W21 and partially through the wire W22.

However, the semiconductor device 1 according to the present comparative example can appear to be operating without trouble even when a bonding defect occurs in one of the wires W11 and W12 (or one of the wires W21 and W22) installed in parallel. Accordingly, even when a bonding defect occurs in the multiple wires, it is difficult to identify the bonding defect from the operation.

### Semiconductor Device (Second Comparative Example)

FIG. 2 is a diagram illustrating a second comparative example of a semiconductor device (which has a typical configuration to be compared with the configurations of the first embodiment and the second embodiment of the present disclosure, which will be described below). A semiconductor device 1 according to the present comparative example has a configuration basically similar to that of the first comparative example (see FIG. 1) described above, and includes a plurality of power transistors M1a and M1b in place of the power transistor M1.

A drain of the power transistor M1a is connected to a pad P11. A source of the power transistor M1a is connected to a pad P21. A gate of the power transistor M1a is connected to a terminal for applying a gate signal G1a.

A drain of the power transistor M1b is connected to a pad P12. A source of the power transistor M1b is connected to a pad P22. A gate of the power transistor M1b is connected to a terminal for applying a gate signal G1b.

Note that each of the power transistors M1a and M1b has the same element size (and thus has the same current rating). Accordingly, when both the power transistors M1a and M1b are in an ON state, a half of an output current Io flows through each of the power transistors M1a and M1b.

In the semiconductor device 1 according to the present comparative example, it is possible to independently control each of the power transistors M1a and M1b. Accordingly, it is possible to determine whether or not a bonding defect has occurred in at least one of wires W11 and W21, by detecting whether or not an electric current flows through a path leading from an input electrode IN to an output electrode OUT through the wire W11, the pad P11, the power transistor M1a, the pad P21, and the wire W21.

In addition, it is possible to determine whether or not a bonding defect has occurred in at least one of wires W12 and W22, by detecting whether or not an electric current flows through a path leading from the input electrode IN to the output electrode OUT through the wire W12, the pad P12, the power transistor M1b, the pad P22, and the wire W22.

However, in the semiconductor device 1 according to the present comparative example, separate back gates need to be provided for the power transistors M1a and M1b to control each of the power transistors M1a and M1b independently. In FIG. 2, the back gate of the power transistor M1a is connected to the source (i.e., the pad P21) of the power transistor M1a. Meanwhile, the back gate of the power transistor M1b is connected to the source (i.e., the pad P22) of the power transistor M1b. This leads to an increase in the element area of each of the power transistors M1a and M1b (and, in turn, an increase in the size of a semiconductor chip 10).

### Semiconductor Device (First Embodiment)

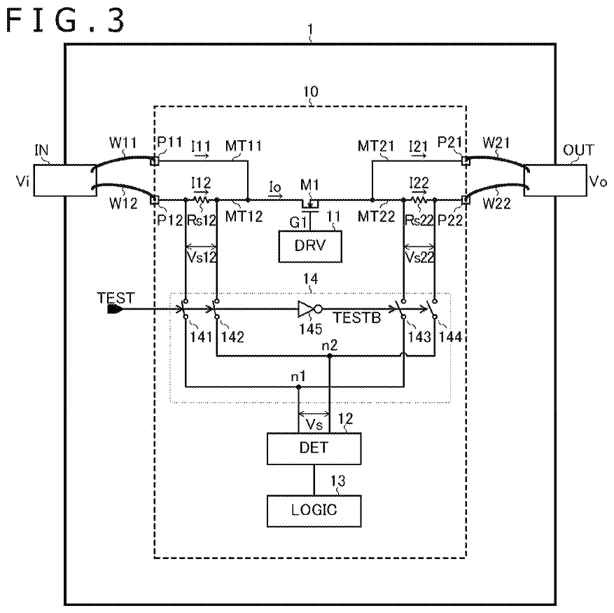

FIG. 3 is a diagram illustrating a semiconductor device 1 according to the first embodiment. The semiconductor device 1 according to the present embodiment is a linear power supply integrated circuit (IC) that generates an output voltage Vo by stepping down an input voltage Vi. In FIG. 3, the semiconductor device 1 according to the present embodiment has a configuration basically similar to that of the first comparative example (see FIG. 1) described above, and further includes a driver 11, a current detection circuit 12, a logic 13, and a multiplexer 14.

The driver 11 performs drive control on a power transistor M1 such that the output voltage Vo (or a feedback voltage Vfb corresponding to the output voltage Vo), which is outputted from a source of the power transistor M1, coincides with a reference voltage Vref.

A metal wire MT11 is installed between a drain of the power transistor M1 and a pad P11 to establish continuity therebetween. In addition, a metal wire MT12 is installed between the drain of the power transistor M1 and a pad P12 to establish continuity therebetween. Branch currents I11 and I12 flow through the metal wires MT11 and MT12, respectively.

Meanwhile, a metal wire MT21 is installed between the source of the power transistor M1 and a pad P21 to establish continuity therebetween. In addition, a metal wire MT22 is installed between the source of the power transistor M1 and a pad P22 to establish continuity therebetween. Branch currents I21 and I22 flow through the metal wires MT21 and MT22, respectively.

Note that, out of the above-mentioned components, the pads P11 and P12 correspond to a plurality of input pads. The pads P21 and P22 correspond to a plurality of output pads. The metal wires MT11 and MT12 correspond to a plurality of input wires. The metal wires MT21 and MT22 correspond to a plurality of output wires.

The current detection circuit 12 detects a sense voltage Vs (i.e., a voltage applied between a node n1 and a node n2) outputted from the multiplexer 14.

The logic 13 determines a condition of wire bonding of each of the pads P11, P12, P21, and P22 according to a result of the detection by the current detection circuit 12. For example, the logic 13 may determine that the condition of wire bonding is defective, when the sense voltage Vs does not coincide with an expected value (the details will be described below).

The multiplexer 14 alternatively outputs, as the sense voltage Vs, any one of sense voltages Vs12 and Vs22 to the current detection circuit 12 according to a test control signal TEST.

The sense voltage Vs12 corresponds to a voltage drop (=I12×Rs12) caused in the metal wire MT12 according to the branch current I12 flowing through the metal wire MT12 and a wire resistance component (i.e., a sense resistor Rs12) of the metal wire MT12. That is, in the semiconductor device 1 according to the present embodiment, two branches of metal wires lead to the drain of the power transistor M1, and one (i.e., the metal wire MT12 in FIG. 3) of the two branches is used as the sense resistor Rs12.

The sense voltage Vs22 corresponds to a voltage drop (=I22×Rs22) caused in the metal wire MT22 according to the branch current I22 flowing through the metal wire MT22 and a wire resistance component (i.e., a sense resistor Rs22) of the metal wire MT22. That is, in the semiconductor device 1 according to the present embodiment, two branches of metal wires lead to the source of the power transistor M1, and one (i.e., the metal wire MT22 in FIG. 3) of the two branches is used as the sense resistor Rs22.

In FIG. 3, the multiplexer 14 includes switches 141, 142, 143, and 144 and an inverter 145.

The switch 141 is connected between a first end of the sense resistor Rs12 and the node n1, and is turned on and off according to the test control signal TEST. For example, the switch 141 enters an ON state when the test control signal TEST is at a high level, and enters an OFF state when the test control signal TEST is at a low level.

The switch 142 is connected between a second end of the sense resistor Rs12 and the node n2, and is turned on and off according to the test control signal TEST. For example, the switch 142 enters an ON state when the test control signal TEST is at the high level, and enters an OFF state when the test control signal TEST is at the low level.

The switch 143 is connected between a first end of the sense resistor Rs22 and the node n1, and is turned on and off according to an inverted test control signal TESTB (which represents a logical inverse of the test control signal TEST). For example, the switch 143 enters an ON state when the inverted test control signal TESTB is at a high level, and enters an OFF state when the inverted test control signal TESTB is at a low level.

The switch 144 is connected between a second end of the sense resistor Rs22 and the node n2, and is turned on and off according to the inverted test control signal TESTB. For example, the switch 144 enters an ON state when the inverted test control signal TESTB is at the high level, and enters an OFF state when the inverted test control signal TESTB is at the low level.

The inverter 145 inverts the logic level of the test control signal TEST to generate the inverted test control signal TESTB. Accordingly, the inverted test control signal TESTB is at the low level when the test control signal TEST is at the high level, and is at the high level when the test control signal TEST is at the low level.

When the test control signal TEST is at the high level, the switches 141 and 142 enter the ON state, and the switches 143 and 144 enter the OFF state. Accordingly, the first and second ends of the sense resistor Rs12 are connected to the nodes n1 and n2, respectively. As a result, the multiplexer 14 outputs the sense voltage Vs12 as the sense voltage Vs.

Here, when no bonding defect has occurred at either of the pads P11 and P12, equal branch currents I11 and I12 (i.e., I11=I12=Io/2) flow through the metal wires MT11 and the MT12, respectively. At this time, the current detection circuit 12 detects that the sense voltage Vs (=I12×Rs12) coincides with the expected value (=(Io/2)×Rs12). The logic 13 determines the condition of wire bonding of each of the pads P11 and P12 to be good, according to this result of the detection.

Meanwhile, when a bonding defect has occurred at the pads P11 and P12, unequal branch currents I11 and I12 flow through the metal wires MT11 and MT12, respectively. For example, in a case where a break has occurred in a wire W11, all of the output current Io flows as the branch current I12. This results in the sense voltage Vs (=I12×Rs12) being higher than the expected value (=(Io/2)×Rs12). Note that, also in a case where the condition of wire bonding at the pad P11 is poor, I11<I12, resulting in the sense voltage Vs being higher than the expected value.

Meanwhile, in a case where a break has occurred in a wire W12, for example, no branch current I12 flows. This results in the sense voltage Vs (=I12×Rs12) being lower than the expected value (=(Io/2)×Rs12). Note that, also in a case where the condition of wire bonding at the pad P12 is poor, I11>I12, resulting in the sense voltage Vs being lower than the expected value.

As described above, when the branch currents I11 and I12 are not equal to each other, the current detection circuit 12 detects that the sense voltage Vs (=I12×Rs12) does not coincide with the expected value (=(Io/2)×Rs12). The logic 13 determines the condition of wire bonding of each of the pads P11 and P12 to be defective, according to this result of the detection.

When the test control signal TEST is at the low level, the switches 141 and 142 enter the OFF state, and the switches 143 and 144 enter the ON state. Accordingly, the first and second ends of the sense resistor Rs22 are connected to the nodes n1 and n2, respectively. As a result, the multiplexer 14 outputs the sense voltage Vs22 as the sense voltage Vs.

Here, when no bonding defect has occurred at either of the pads P21 and P22, equal branch currents I21 and I22 (i.e., I21=I22=Io/2) flow through the metal wires MT21 and MT22, respectively. At this time, the current detection circuit 12 detects that the sense voltage Vs (=I22×Rs22) coincides with the expected value (=(Io/2)×Rs22). The logic 13 determines the condition of wire bonding of each of the pads P21 and P22 to be good, according to this result of the detection.

Meanwhile, when a bonding defect has occurred at the pads P21 and P22, unequal branch currents I21 and I22 flow through the metal wires MT21 and MT22, respectively. For example, in a case where a break has occurred in a wire W21, all of the output current Io flows as the branch current I22. This results in the sense voltage Vs (=I22×Rs22) being higher than the expected value (=(Io/2)×Rs22). Note that, also in a case where the condition of wire bonding at the pad P21 is poor, I21<I22, resulting in the sense voltage Vs being higher than the expected value.

Meanwhile, in a case where a break has occurred in a wire W22, for example, no branch current I22 flows. This results in the sense voltage Vs (=I22×Rs22) being lower than the expected value (=(Io/2)×Rs22). Note that, also in a case where the condition of wire bonding at the pad P22 is poor, I21>I22, resulting in the sense voltage Vs being lower than the expected value.

As described above, when the branch currents I21 and I22 are not equal to each other, the current detection circuit 12 detects that the sense voltage Vs (=I22×Rs22) does not coincide with the expected value (=(Io/2)×Rs22). The logic 13 determines the condition of wire bonding of each of the pads P21 and P22 to be defective, according to this result of the detection.

According to the semiconductor device 1 according to the present embodiment, the condition of wire bonding of each of the pads P11 and P12 after assembly of the semiconductor device 1 can be determined by detecting at least one of the branch currents I11 and I12 that flow through the pads P11 and P12, respectively, and determining whether or not the detected branch current coincides with an expected value.

Similarly, according to the semiconductor device 1 according to the present embodiment, the condition of wire bonding of each of the pads P21 and P22 after the assembly of the semiconductor device 1 can be determined by detecting at least one of the branch currents I21 and I22 that flow through the pads P21 and P22, respectively, and determining whether or not the detected branch current coincides with an expected value.

In addition, the semiconductor device 1 according to the present embodiment eliminates the need to divide the power transistor M1 into a plurality of transistors and control each of the plurality of transistors independently, unlike the second comparative example (see FIG. 2) described above. This leads to preventing an increase in the element area of the power transistor M1 (and, in turn, preventing an increase in the size of a semiconductor chip 10).

Further, provision of the multiplexer 14 enables the single current detection circuit 12 to be used as a section for detecting each of the branch currents I12 and I22. This leads to a reduced circuit size compared to a case where a separate current detection circuit is provided for each of input and output sides.

Note that the multiplexer 14 preferably outputs the sense voltages Vs12 and Vs22 sequentially in a test mode. This sequential output can be accomplished by switching the level of the test control signal TEST from the high level to the low level (or from the low level to the high level) in the test mode.

In addition, preferably, the multiplexer 14 continuously outputs one of the sense voltages Vs12 and Vs22 in a non-test mode. This continuous output can be accomplished by fixing the test control signal TEST at the high level (or the low level) in the non-test mode.

Note that, in the above non-test mode, the current detection circuit 12 preferably functions as an overcurrent protection circuit that detects the sense voltage Vs and controls the driver 11 to limit the output current Io flowing through the power transistor M1. Such a configuration enables the current detection circuit 12 to be utilized not only in the test mode but also in the non-test mode.

### Semiconductor Device (Second Embodiment)

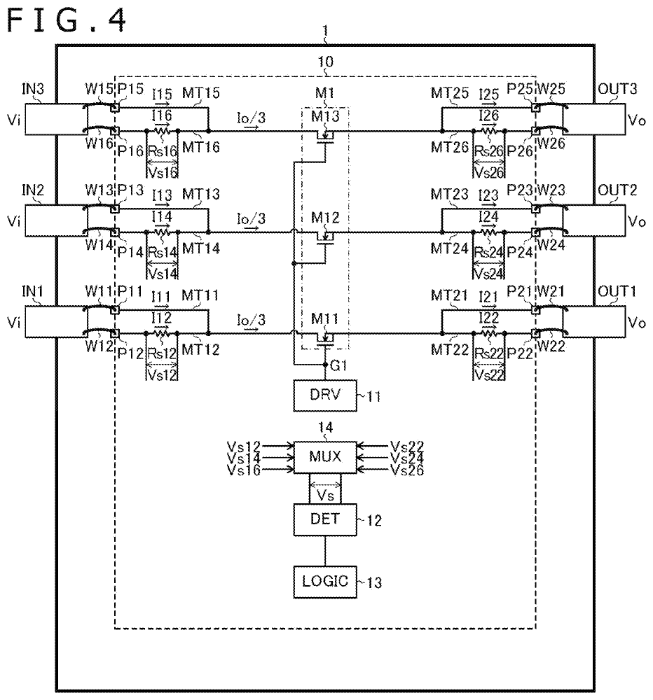

FIG. 4 is a diagram illustrating a semiconductor device 1 according to the second embodiment. The semiconductor device 1 according to the present embodiment has a configuration basically similar to that of the first embodiment (see FIG. 3) described above, and is provided with a plurality of input electrodes IN and a plurality of output electrodes OUT described above. In FIG. 4, the semiconductor device 1 includes a semiconductor chip 10, input electrodes IN1, IN2, and IN3, output electrodes OUT1, OUT2, and OUT3, and wires W11, W12, W13, W14, W15, W16, W21, W22, W23, W24, W25, and W26 encapsulated in a package.

In addition, the power transistor M1 described above is divided into three power transistors M11, M12, and M13 (corresponding to unit transistors) with respective gates thereof connected in common to each other.

Note that each of the power transistors M11 to M13 has the same element size (and thus has the same current rating). Accordingly, a unit output current Io/3, which is one third of an output current Io that flows through the power transistor M1 as a whole, flows through each of the power transistors M11 to M13.

Further, the semiconductor chip 10 includes pads P11, P12, P13, P14, P15, P16, P21, P22, P23, P24, P25, and P26 to achieve electrical continuity with each of the input electrodes IN1 to IN3 and the output electrodes OUT1 to OUT3.

A drain of the power transistor M11 is connected to each of the pads P11 and P12. A source of the power transistor M11 is connected to each of the pads P21 and P22. A gate of the power transistor M11 is connected to a terminal (i.e., an output terminal of a driver 11) for applying a gate signal G1.

A drain of the power transistor M12 is connected to each of the pads P13 and P14. A source of the power transistor M12 is connected to each of the pads P23 and P24. A gate of the power transistor M12 is connected to the terminal (i.e., the output terminal of the driver 11) for applying the gate signal G1.

A drain of the power transistor M13 is connected to each of the pads P15 and P16. A source of the power transistor M13 is connected to each of the pads P25 and P26. A gate of the power transistor M13 is connected to the terminal (i.e., the output terminal of the driver 11) for applying the gate signal G1.

Each of the input electrodes IN1 to IN3 is an external electrode to which an input voltage Vi is applied. Note that one end of each of the input electrodes IN1 to IN3 is exposed from the package of the semiconductor device 1.

Each of the output electrodes OUT1 to OUT3 is an external electrode to which an output voltage Vo is applied. Note that one end of each of the output electrodes OUT1 to OUT3 is exposed from the package of the semiconductor device 1.

The wire W11 is installed in such a manner as to establish bonding between another end of the input electrode IN1 and the pad P11 of the semiconductor chip 10. The wire W12 is installed in such a manner as to establish bonding between the other end of the input electrode IN1 and the pad P12 of the semiconductor chip 10. The wire W13 is installed in such a manner as to establish bonding between another end of the input electrode IN2 and the pad P13 of the semiconductor chip 10. The wire W14 is installed in such a manner as to establish bonding between the other end of the input electrode IN2 and the pad P14 of the semiconductor chip 10. The wire W15 is installed in such a manner as to establish bonding between another end of the input electrode IN3 and the pad P15 of the semiconductor chip 10. The wire W16 is installed in such a manner as to establish bonding between the other end of the input electrode IN3 and the pad P16 of the semiconductor chip 10.

The wire W21 is installed in such a manner as to establish bonding between another end of the output electrode OUT1 and the pad P21 of the semiconductor chip 10. The wire W22 is installed in such a manner as to establish bonding between the other end of the output electrode OUT1 and the pad P22 of the semiconductor chip 10. The wire W23 is installed in such a manner as to establish bonding between another end of the output electrode OUT2 and the pad P23 of the semiconductor chip 10. The wire W24 is installed in such a manner as to establish bonding between the other end of the output electrode OUT2 and the pad P24 of the semiconductor chip 10. The wire W25 is installed in such a manner as to establish bonding between another end of the output electrode OUT3 and the pad P25 of the semiconductor chip 10. The wire W26 is installed in such a manner as to establish bonding between the other end of the output electrode OUT3 and the pad P26 of the semiconductor chip 10.

Note that each of the pads P11 to P16 and the wires W11 to W16 is a portion of a current path through which the output current Io (more precisely, a branch current of the output current Io) flows, and is not dedicated to current detection. This similarly applies to each of the pads P21 to P26 and the wires W21 to W26.

A metal wire MT11 is installed between the drain of the power transistor M11 and the pad P11 to establish continuity therebetween. A metal wire MT12 is installed between the drain of the power transistor M11 and the pad P12 to establish continuity therebetween. Branch currents I11 and I12 flow through the metal wires MT11 and MT12, respectively. A voltage drop caused in the metal wire MT12 according to the branch current I12 flowing through the metal wire MT12 and a wire resistance component (i.e., a sense resistor Rs12) of the metal wire MT12 is outputted, as a sense voltage Vs12 (=I12×Rs12), to a multiplexer 14.

A metal wire MT13 in installed between the drain of the power transistor M12 and the pad P13 to establish continuity therebetween. A metal wire MT14 is installed between the drain of the power transistor M12 and the pad P14 to establish continuity therebetween. Branch currents I13 and I14 flow through the metal wires MT13 and MT14, respectively. A voltage drop caused in the metal wire MT14 according to the branch current I14 flowing through the metal wire MT14 and a wire resistance component (i.e., a sense resistor Rs14) of the metal wire MT14 is outputted, as a sense voltage Vs14 (=I14×Rs14), to the multiplexer 14.

A metal wire MT15 is installed between the drain of the power transistor M13 and the pad P15 to establish continuity therebetween. A metal wire MT16 is installed between the drain of the power transistor M13 and the pad P16 to establish continuity therebetween. Branch currents I15 and I16 flow through the metal wires MT15 and MT16, respectively. A voltage drop caused in the metal wire MT16 according to the branch current I16 flowing through the metal wire MT16 and a wire resistance component (i.e., a sense resistor Rs16) of the metal wire MT16 is outputted, as a sense voltage Vs16 (=I16×Rs16), to the multiplexer 14.

A metal wire MT21 is installed between the source of the power transistor M11 and the pad P21 to establish continuity therebetween. A metal wire MT22 is installed between the source of the power transistor M11 and the pad P22 to establish continuity therebetween. Branch currents I21 and I22 flow through the metal wires MT21 and MT22, respectively. A voltage drop caused in the metal wire MT22 according to the branch current I22 flowing through the metal wire MT22 and a wire resistance component (i.e., a sense resistor Rs22) of the metal wire MT22 is outputted, as a sense voltage Vs22 (=I22×Rs22), to the multiplexer 14.

A metal wire MT23 is installed between the source of the power transistor M12 and the pad P23 to establish continuity therebetween. A metal wire MT24 is installed between the source of the power transistor M12 and the pad P24 to establish continuity therebetween. Branch currents I23 and I24 flow through the metal wires MT23 and MT24, respectively. A voltage drop caused in the metal wire MT24 according to the branch current I24 flowing through the metal wire MT24 and a wire resistance component (i.e., a sense resistor Rs24) of the metal wire MT24 is outputted, as a sense voltage Vs24 (=I24×Rs24), to the multiplexer 14.

A metal wire MT25 is installed between the source of the power transistor M13 and the pad P25 to establish continuity therebetween. A metal wire MT26 is installed between the source of the power transistor M13 and the pad P26 to establish continuity therebetween. Branch currents I25 and I26 flow through the metal wires MT25 and MT26, respectively. A voltage drop caused in the metal wire MT26 according to the branch current I26 flowing through the metal wire MT26 and a wire resistance component (i.e., a sense resistor Rs26) of the metal wire MT26 is outputted, as a sense voltage Vs26 (=I26×Rs26), to the multiplexer 14.

The multiplexer 14 alternatively outputs, as a sense voltage Vs, any one of the sense voltages Vs12, Vs14, Vs16, Vs22, Vs24, and Vs26 to a current detection circuit 12.

The current detection circuit 12 detects the sense voltage Vs outputted from the multiplexer 14.

A logic 13 determines a condition of wire bonding of each of the pads P11 to P16 and P21 to P26 according to a result of the detection by the current detection circuit 12.

As described above, the method for determining the condition of wire bonding described above is applicable also to the semiconductor device 1 that is provided with the plurality of input electrodes IN1 to IN3 and the plurality of output electrodes OUT1 to OUT3.

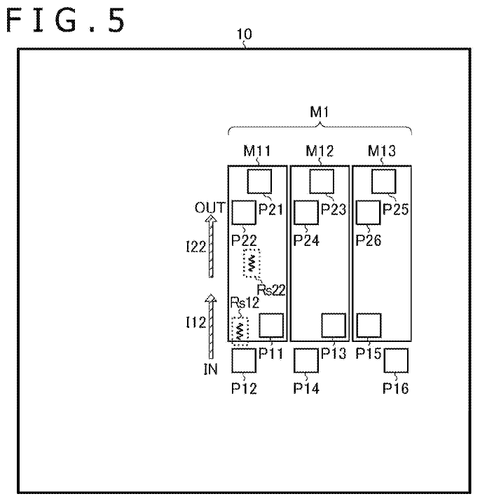

FIG. 5 is a diagram illustrating a circuit layout (in which the metal wires are not depicted) of the semiconductor chip 10 according to the second embodiment. Note that hatched arrows in FIG. 5 represent the branch current I12 flowing from the pad P12 to the power transistor M11 and the branch current I22 flowing from the power transistor M11 to the pad P22.

The power transistors M11 to M13 are each formed in a rectangular shape to have the same element size in a plan view of the semiconductor chip 10. In FIG. 5, each of the power transistors M11 to M13 is formed in the shape of a rectangle having right and left long sides extending in the vertical direction of the page and upper and lower short sides extending in the horizontal direction of the page. In addition, the power transistors M11 to M13 are arranged from left to right on the page in the order of M11, M12, and M13.

The pad P11 is disposed on an element-forming region of the power transistor M11 (at a bottom right corner thereof in FIG. 5). The pad P12 is disposed outside of the element-forming region of the power transistor M11 (in the vicinity of a left end of the lower side in FIG. 5). The pad P13 is disposed on an element-forming region of the power transistor M12 (at a bottom right corner thereof in FIG. 5). The pad P14 is disposed outside of the element-forming region of the power transistor M12 (in the vicinity of a left end of the lower side in FIG. 5). The pad P15 is disposed on an element-forming region of the power transistor M13 (at a bottom left corner thereof in FIG. 5). The pad P16 is disposed outside of the element-forming region of the power transistor M13 (in the vicinity of a right end of the lower side in FIG. 5).

Meanwhile, the pad P21 is disposed on the element-forming region of the power transistor M11 (in the vicinity of a middle of the upper side in FIG. 5). The pad P22 is disposed on the element-forming region of the power transistor M11 (in the vicinity of an upper end of the left side and on the lower side of the pad P21 in FIG. 5). The pad P23 is disposed on the element-forming region of the power transistor M12 (in the vicinity of a middle of the upper side in FIG. 5). The pad P24 is disposed on the element-forming region of the power transistor M12 (in the vicinity of an upper end of the left side and on the lower side of the pad P23 in FIG. 5). The pad P25 is disposed on the element-forming region of the power transistor M13 (in the vicinity of a middle of the upper side in FIG. 5). The pad P26 is disposed on the element-forming region of the power transistor M13 (in the vicinity of an upper end of the left side and on the lower side of the pad P25 in FIG. 5).

In addition, as indicated by dotted-line frames in FIG. 5, the metal wires that serve as the sense resistors Rs12 and Rs22, respectively, are installed on the element-forming region of the power transistor M11 (at the bottom left corner and at a position slightly toward the left side in the middle in FIG. 5). This leads to an increase in area efficiency of the semiconductor chip 10. Moreover, a need to disrupt a layout of the power transistor M1 does not arise.

Note that, although not explicitly illustrated in FIG. 5, the metal wires that serve as the sense resistors Rs14, Rs16, Rs24, and Rs26, respectively, may also be installed on the element-forming regions of the corresponding power transistors M12 and M13 as described above.

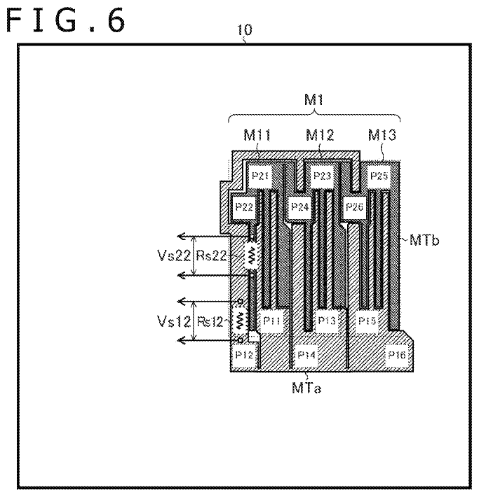

FIG. 6 is a diagram illustrating the circuit layout (in which the metal wires are depicted) of the semiconductor chip 10 according to the second embodiment. In FIG. 6, metal wires MTa and MTb are depicted in such a manner as to be superposed upon the power transistors M11 to M13 (which are represented by thin dotted lines in FIG. 6) of FIG. 5.

As illustrated in FIG. 6, the plurality of metal wires MTa and MTb are formed on an element-forming region of the power transistor M1 (i.e., of each of the power transistors M11 to M13).

The metal wire MTa is formed in such a manner as to extend from outside of the lower side of each of the power transistors M11 to M13 to cover each of the pads P11 to P16, and to have a plurality of comb tooth-like projection portions each extending onto the element-forming region of the corresponding one of the power transistors M11 to M13, in the plan view of the semiconductor chip 10. Further, the metal wire MTa includes a portion that extends from a region outside of the left side of the power transistor M11 to regions outside of the upper sides of the power transistors M12 and M13 through a top left corner of the power transistor M11 and that extends onto the element-forming regions of the power transistors M12 and M13. The metal wire MTa may thus be formed in such a manner as to establish continuity between each of the pads P11 to P16 and the drain of the corresponding one of the power transistors M11 to M13. Note that a portion of the metal wire MTa can be understood to correspond to the above-mentioned metal wire MT12 that serves as the sense resistor Rs12.

The metal wire MTb is formed in such a manner as to extend from a region in the vicinity of the upper side of each of the power transistors M11 to M13 to cover each of the pads P21 to P26, and to have a plurality of comb tooth-like projection portions each extending downward on the page on the element-forming region of the corresponding one of the power transistors M11 to M13, in the plan view of the semiconductor chip 10. The metal wire MTb may thus be formed in such a manner as to establish continuity between each of the pads P21 to P26 and the source of the corresponding one of the power transistors M11 to M13. Note that a portion of the metal wire MTb can be understood to correspond to the above-mentioned metal wire MT22 that serves as the sense resistor Rs22. In addition, the comb tooth-like projection portions of the metal wire MTa and the comb tooth-like projection portions of the metal wire MTb are laid out in such a manner as to mesh with each other. This contributes to preventing a concentration of an electric current at any of the drains and the sources.

Note that, as illustrated in FIG. 6, portions of the metal wires MTa and MTb which serve as the sense resistors Rs12 and Rs22, respectively, are installed on the element-forming region of the power transistor M11 (at the bottom left corner and at the position slightly toward the left side in the middle in FIG. 6). This leads to an increase in the area efficiency of the semiconductor chip 10 compared to a case where the sense resistors Rs12 and Rs22 are disposed outside of the element-forming region of the power transistor M1.

### <Overview>

The various embodiments described above are summarized as follows.

For example, a semiconductor chip disclosed herein includes a power transistor, a plurality of pads, a plurality of wires arranged to establish continuity between each of the plurality of pads and a first end or a second end of the power transistor, a current detection circuit configured to detect, as a sense voltage, at least one of voltage drops caused in each of the plurality of wires according to a branch current flowing through the wire and a wire resistance component of the wire, and a logic configured to determine a condition of wire bonding of each of the plurality of pads according to a result of the detection by the current detection circuit (a first configuration).

The semiconductor chip having the above first configuration may be configured such that the logic determines the condition of wire bonding to be defective, when the sense voltage does not coincide with an expected value (a second configuration).

Also, the semiconductor chip having the above first or second configuration may be configured such that any of the plurality of wires from which the sense voltage is derived is installed on an element-forming region of the power transistor (a third configuration).

Also, the semiconductor chip having any one of the above first to third configurations may be configured such that the plurality of pads include a plurality of input pads and a plurality of output pads, the plurality of wires include a plurality of input wires arranged to establish continuity between each of the plurality of input pads and the first end of the power transistor, and a plurality of output wires arranged to establish continuity between each of the plurality of output pads and the second end of the power transistor, and the semiconductor chip further includes a multiplexer configured to alternatively output, as the sense voltage, any one of a first sense voltage caused in at least one of the plurality of input wires and a second sense voltage caused in at least one of the plurality of output wires to the current detection circuit (a fourth configuration).

Also, the semiconductor chip having the above fourth configuration may be configured such that the multiplexer outputs the first sense voltage and the second sense voltage sequentially in a test mode (a fifth configuration).

Also, the semiconductor chip having the above fourth or fifth configuration may be configured such that the multiplexer continuously outputs one of the first sense voltage and the second sense voltage in a non-test mode (a sixth configuration).

Also, the semiconductor chip having any one of the above first to sixth configurations may be configured such that the power transistor is divided into a plurality of unit transistors having respective control terminals connected in common to each other (a seventh configuration).

Also, the semiconductor chip having the above seventh configuration may be configured such that each of the plurality of unit transistors has the same current rating (an eighth configuration).

Also, the semiconductor chip having any one of the above first to eighth configurations may further include a driver configured to perform drive control on the power transistor such that an output voltage outputted from the power transistor or a feedback voltage corresponding to the output voltage coincides with a reference voltage (a ninth configuration).

Also, for example, a semiconductor device disclosed herein includes the semiconductor chip having any one of the above first to ninth configurations, a plurality of external electrodes, and wires arranged to establish bonding between the plurality of external electrodes and the plurality of pads (a tenth configuration).

### Other Example Modifications

Note that the various technical features disclosed herein may be modified in a variety of manners without departing from the gist of the above-described embodiments or technical ingenuity thereof.

Also note that the various technical features disclosed herein are applicable not only to the linear power supply IC (e.g., a low-dropout (LDO) regulator) described above, but to power supplies in general (in particular, a primary power supply of an in-vehicle battery, for example), including a direct current to direct current (DC/DC) converter and so on. Further, the various technical features disclosed herein are applicable to all circuits (switch circuits, inverter circuits, etc.) that involve use of a power transistor.

That is, the above-described embodiments should be considered to be in all examples illustrative and not restrictive. In addition, the technical scope of the present disclosure should be understood to be defined by the appended claims, and to encompass all modifications that fall within the scope and spirit of the appended claims and equivalents thereof.

The present disclosure makes it possible to provide a semiconductor chip and a semiconductor device which enable detection of a bonding defect of each of a plurality of wires installed in parallel.

What is claimed is:

1. A semiconductor chip comprising:
a power transistor;
a plurality of pads;
a plurality of wires arranged to establish continuity between each of the plurality of pads and a first end or a second end of the power transistor;
a current detection circuit configured to detect, as a sense voltage, at least one of voltage drops caused in each of the plurality of wires according to a branch current flowing through the wire and a wire resistance component of the wire; and
a logic configured to determine a condition of wire bonding of each of the plurality of pads according to a result of the detection by the current detection circuit.

2. The semiconductor chip according to claim 1, wherein the logic determines the condition of wire bonding to be defective, when the sense voltage does not coincide with an expected value.

3. The semiconductor chip according to claim 1, wherein any of the plurality of wires from which the sense voltage is derived is installed on an element-forming region of the power transistor.

4. The semiconductor chip according to claim 1, wherein
the plurality of pads include a plurality of input pads and a plurality of output pads,
the plurality of wires include a plurality of input wires arranged to establish continuity between each of the plurality of input pads and the first end of the power transistor, and a plurality of output wires arranged to establish continuity between each of the plurality of output pads and the second end of the power transistor, and
the semiconductor chip further includes a multiplexer configured to alternatively output, as the sense voltage, any one of a first sense voltage caused in at least one of the plurality of input wires and a second sense voltage caused in at least one of the plurality of output wires to the current detection circuit.

5. The semiconductor chip according to claim 4, wherein the multiplexer outputs the first sense voltage and the second sense voltage sequentially in a test mode.

6. The semiconductor chip according to claim 5, wherein the multiplexer continuously outputs one of the first sense voltage and the second sense voltage in a non-test mode.

7. The semiconductor chip according to claim 1, wherein the power transistor is divided into a plurality of unit transistors having respective control terminals connected in common to each other.

8. The semiconductor chip according to claim 7, wherein each of the plurality of unit transistors has same current rating.

9. The semiconductor chip according to claim 1, further comprising:
a driver configured to perform drive control on the power transistor such that an output voltage outputted from the power transistor or a feedback voltage corresponding to the output voltage coincides with a reference voltage.

10. A semiconductor device comprising:
the semiconductor chip of claim 1;
a plurality of external electrodes; and
wires arranged to establish bonding between the plurality of external electrodes and the plurality of pads.
